(19) United States
(12) Patent Application Publication
(10) Pub. No.: US 2020/0385885 A1
(43) Pub. Date: Dec. 10, 2020

(54) CYCLICAL EPITAXIAL DEPOSITION SYSTEM

(71) Applicant: GOLD CARBON CO.,LTD., Taoyuan City (TW)

(72) Inventors: CHIEN-TE HSIEH, Taoyuan City (TW); Yeou-Fu Lin, Taoyuan City (TW); CHIA-HUNG CHAO, Taoyuan City (TW)

(21) Appl. No.: 16/862,760

(22) Filed: Apr. 30, 2020

(30) Foreign Application Priority Data
Jun. 4, 2019 (TW) 108119349

(51) Int. Cl. C30B 25/02; C30B 25/14; C30B 25/10; C23C 16/455; C23C 16/46; C23C 16/02; C23C 16/44; H01J 37/32

(52) U.S. Cl. CPC C30B 25/025; C30B 25/14; C30B 25/10; C23C 16/45551; C23C 16/463; H01J 2237/002; C23C 16/4408; C23C 16/0227; H01J 37/3244; H01J 2237/3321; C23C 16/0209

(57) ABSTRACT

A cyclical epitaxial deposition system is provided. The cyclical epitaxial deposition system includes a deposition chamber, a conveyance device, and a gas distribution module. The conveyance device is used to continuously convey a substrate to pass through the deposition chamber along a conveyance path.

The gas distribution module is disposed in the deposition chamber and located above the conveyance path. The gas distribution module includes a plurality of precursor gas nozzles and purge gas nozzles that are not in communication with one another so as to guide at least one precursor gas and at least one purge gas to different regions of the substrate at the same time.

### CROSS-REFERENCE TO RELATED PATENT APPLICATION

This application claims the benefit of priority to Taiwan Patent Application No. 108119349, filed on Jun. 4, 2019. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to an epitaxial deposition system, and more particularly to a cyclical epitaxial deposition system using a principle of atomic layer deposition.

### BACKGROUND OF THE DISCLOSURE

Atomic layer deposition (ALD) is a vapor phase technique used to grow high-quality thin films Compared with a film layer formed by means of chemical vapor deposition or physical vapor deposition, a film layer formed by atomic layer deposition has relatively high density, thickness uniformity, and step coverage. In addition, the thickness of the film layer can be precisely controlled by use of atomic layer deposition. Therefore, the atomic layer deposition technique is applied in manufacturing processes of electronic elements.

During atomic layer deposition, in each depositing cycle, two different precursor gases are sequentially introduced into a deposition chamber at different time points, rather than at the same time. The precursor gas introduced each time reacts with the surface of a substrate in a self-limiting manner to form a monoatomic layer. A film layer having a particular thickness can be formed only after multiple deposition cycles.

Therefore, compared with chemical vapor deposition, a fabrication process using atomic layer deposition takes a relatively longer time, and currently cannot be applied in continuous production, thus being inapplicable in manufacturing elements or devices requiring mass production.

### SUMMARY OF THE DISCLOSURE

The technical problem to be solved by the present disclosure is to provide a cyclical epitaxial deposition system so as to shorten deposition time in the use of an atomic layer deposition technique.

In one aspect, the present disclosure provides a cyclical epitaxial deposition system, which includes a deposition chamber, a conveyance device, and a gas distribution module. The conveyance device is used to continuously convey a substrate to/out of the deposition chamber along a conveyance path. The gas distribution module is disposed in the deposition chamber and located above the conveyance path. The gas distribution module includes a plurality of precursor gas nozzles and purge gas nozzles that are not in communication with one another so as to guide at least one precursor gas and at least one purge gas to different regions of the substrate at the same time.

Therefore, the present disclosure achieves the following advantageous effects. In the cyclical epitaxial deposition system provided in the present disclosure, a conveyance device is used to continuously convey a substrate to/out of a deposition chamber along a conveyance path, and a gas distribution module includes a plurality of precursor gas nozzles and at least one purge gas nozzle that are not in communication with one another, so as to guide at least one precursor gas and at least one purge gas to different regions of the substrate at the same time. By using the foregoing technical solutions, a film layer can be continuously formed on the substrate and deposition time can be shortened. Thus, the present disclosure is applicable in manufacturing elements or devices requiring mass production.

To further understand the features and technical content of the present disclosure, reference is made to the following detailed description and drawings related to the present disclosure. However, the provided drawings are merely used for reference and description, and not intended to limit the present disclosure.

### BRIEF DESCRIPTION OF THE DRAWINGS

FIG. 1 is a schematic diagram of a cyclical epitaxial deposition system of the present disclosure; and

FIG. 2 is a schematic diagram of a gas distribution module in an embodiment of the present disclosure.

FIG. 3 is a schematic diagram of a gas distribution module in another embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

The following describes an implementation manner of the present disclosure relating to “a cyclical epitaxial deposition system” through specific embodiments. Those skilled in the art can easily understand the advantages and effects of the present disclosure from the content disclosed in the specification. The present disclosure can be embodied or applied through other different embodiments. Based on different opinions and applications, the details in the present specification can also be modified and changed without departing from the concept of the present disclosure. In addition, it should be stated first that the accompanying drawings of the present disclosure are merely for brief illustration and not drawn according to actual dimensions. The following embodiments will further explain the related technical content of the present disclosure, but the disclosed content is not intended to limit the scope of protection of the present disclosure.

It should be understood that, although the terms “first”, “second”, “third”, and the like are probably used herein to describe various elements, these elements should not be limited by these terms. The use of these terms only aims to distinguish one element from another. In addition, the term “or” as used herein shall, according to the actual situation, include any one or a combination of more of the associated listed items.

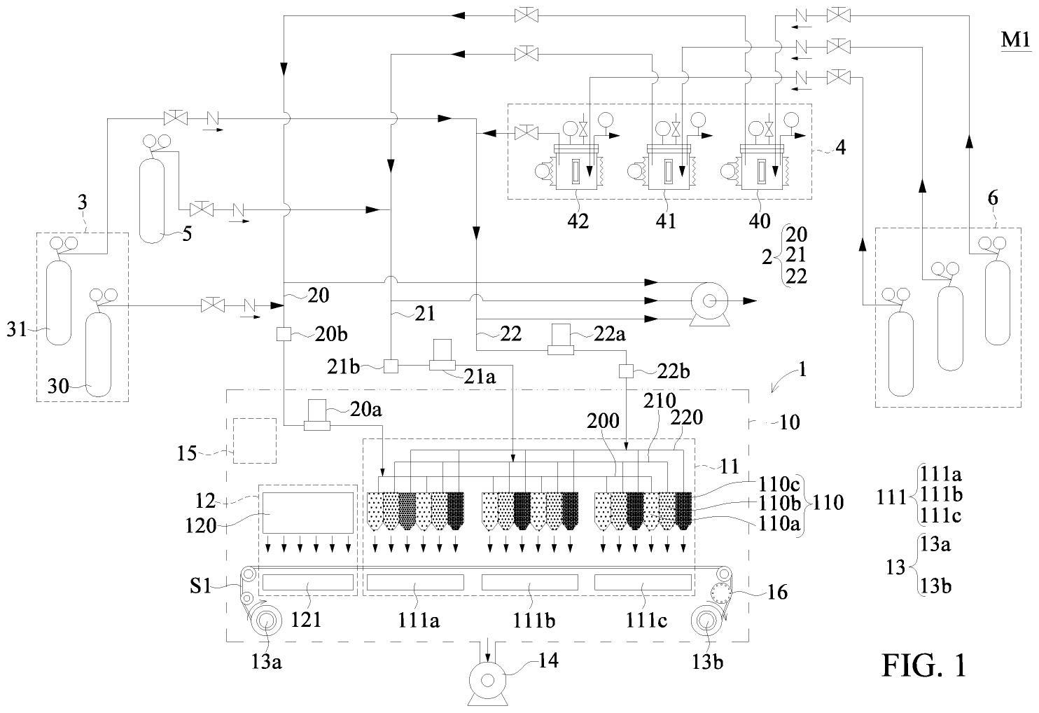

Reference is made to FIG. 1, which is a schematic diagram of a cyclical epitaxial deposition system in an embodiment of the present disclosure. It should be noted that the cyclical epitaxial deposition system M1 in the embodiment of the present disclosure is used to fabricate a particular film layer, such as a platinum layer, aluminum oxide layer, nickel oxide layer, tin oxide layer, titanium oxide layer, iron oxide layer, zinc oxide layer, lithium phosphorus oxynitride (LiPON) layer, or titanium nitride layer, on a substrate S1 based on a principle of atomic layer deposition (or atomic layer epitaxy). In addition, the cyclical epitaxial deposition system M1 in the embodiment of the present disclosure can be applied in a roll-to-roll continuous fabrication process.

As shown in FIG. 1, the cyclical epitaxial deposition system M1 at least includes a vacuum apparatus 1. The vacuum apparatus 1 includes a main chamber 10, a deposition chamber 11, a pre-processing chamber 12, a conveyance device 13, and a gas evacuation device 14.

The deposition chamber 11 and the pre-processing chamber 12 are both disposed inside the main chamber 10 and respectively define individual spaces, so as to prevent mutual diffusion of gases that are respectively introduced to the pre-processing chamber 12 and the deposition chamber 11. In an embodiment, the deposition chamber 11 has two openings (not shown in the figure) respectively located at two opposite thereof to allow the substrate S1 to be conveyed to or out of the deposition chamber 11.

The conveyance device 13 is used to continuously convey the substrate S1 to pass through the pre-processing chamber 12 and the deposition chamber 11 along a conveyance path. Specifically, the pre-processing chamber 12 and the deposition chamber 11 are located at the conveyance path of the substrate S1. By continuous conveyance of the substrate S1 with the conveyance device 13, different sections of the substrate S1, namely, a section in the pre-processing chamber 12 and another section in the deposition chamber 11, can be simultaneously subjected to pre-processing and film deposition.

The conveyance device 13 includes a first feeding and receiving module 13a and a second feeding and receiving module 13b which define the conveyance path of the substrate S1. Specifically, the substrate S1 is driven by the first feeding and receiving module 13a to be continuously conveyed to the pre-processing chamber 12 and the deposition chamber 11, and after processing, the substrate S1 conveyed out of the deposition chamber 11 is rolled up by the second feeding and receiving module 13b.

In this embodiment, the first feeding and receiving module 13a may include a first feeding and receiving reel and a first drive element connected to the axis of the first feeding and receiving reel. Likewise, the second feeding and receiving module 13b may include a second feeding and receiving reel and a second drive element connected to the axis of the second feeding and receiving reel.

The first drive element and the second drive element receive an instruction from a control module to simultaneously drive the first feeding and receiving reel and the second feeding and receiving reel to rotate (clockwise), so that the substrate 51 wound on the first feeding and receiving reel is continuously conveyed to the pre-processing chamber 12 and the deposition chamber 11.

In addition, the first feeding and receiving module 13a may optionally include a first guide roller used to change a conveyance direction of the substrate S1. Likewise, the second feeding and receiving module 13b may optionally include a second guide roller used to change an advancing direction of the substrate S1 conveyed out of the deposition chamber 11.

It should be noted that, in this embodiment, the first feeding and receiving module 13a and the second feeding and receiving module 13b may also change a moving direction of the substrate S1. Specifically, the first drive element and the second drive element receive an instruction from the control module to drive the first feeding and receiving reel and the second feeding and receiving reel to rotate in an opposite direction (counterclockwise), so that the substrate S1 reciprocates in the deposition chamber 11. In this way, a deposition cycle can be repeated for many times in the deposition chamber, to form multiple molecular layers on the substrate S1.

However, the conveyance device 13 in the embodiment of the present disclosure is not limited thereto. In another embodiment, the conveyance device 13 includes a conveyance belt which can continuously convey a work piece to be coated to/out of the pre-processing chamber 12 and the deposition chamber 11.

Referring to FIG. 1, in the cyclical epitaxial deposition system M1 in the embodiment of the present disclosure, the substrate S1 enters the pre-processing chamber 12 before entering the deposition chamber 11, to be subjected to a surface treatment. Thus, the pre-processing chamber 12 and the deposition chamber 11 are sequentially disposed at the conveyance path according to a moving direction of the substrate S1 and are isolated from each other.

In addition, the cyclical epitaxial deposition system M1 further includes a plasma device 120 located in the pre-processing chamber 12. In an embodiment, oxygen, nitrogen, or argon may be introduced into the pre-processing chamber 12 to generate oxygen plasma, nitrogen plasma, or argon plasma. In this way, while the substrate S1 is continuously conveyed to the pre-processing chamber 12, a surface treatment can be performed on the surface of the substrate S1 by using the plasma generated by the plasma device 120. The surface treatment is, for example, cleaning the surface of the substrate S1 or increasing functional groups in quantity on the surface of substrate S1.

In addition, the cyclical epitaxial deposition system M1 in this embodiment further includes a pre-processing heating module 121 which is disposed in the pre-processing chamber 12 corresponding to the conveyance path, so as to heat the substrate S1. It should be noted that, the pre-processing chamber 12 and the plasma device 120 are optional elements, and may be omitted in other embodiments.

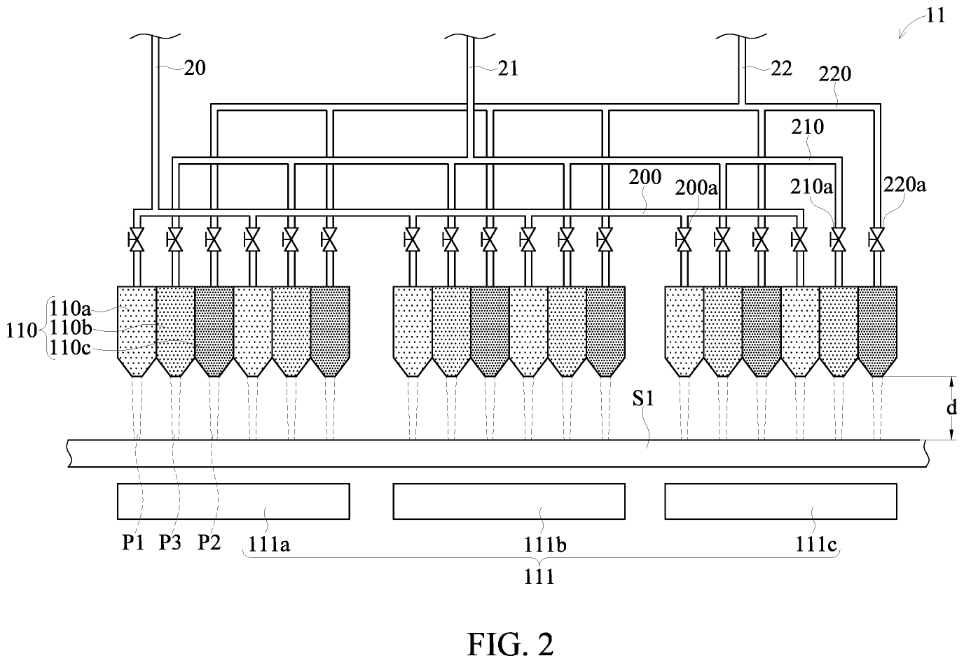

The substrate S1 that has been subjected to the surface treatment can be conveyed by the conveyance device 13 from the pre-processing chamber 12 to the deposition chamber 11 so as to be deposited with a film layer. Referring to FIGS. 1 and 2, FIG. 2 is a schematic diagram of a gas distribution module in an embodiment of the present disclosure.

The gas distribution module 110 is disposed in the deposition chamber 11 and located above the conveyance path. It should be noted that, the system diagram shown in FIG. 1 is merely exemplified for description, and is not intended to limit a relative arrangements of the plasma device 120 and the gas distribution module 110. In an embodiment, the plasma device 120 in the pre-processing chamber 12 and the gas distribution module 110 are arranged in a horizontal direction. In another embodiment, the plasma device 120 and the gas distribution module 110 are arranged in directions forming an included angle. That is to say, a part of the surface of the substrate S1 to be processed in the pre-processing chamber 12 and another part of the surface of the substrate S1 to be processed in the deposition chamber 11 face different directions.

The gas distribution module 110 includes a plurality of precursor gas nozzles 110a and 110c that are not in communication with one another and at least one purge gas nozzle 110b (the figure shows an example in which there is a plurality of purge gas nozzles), so as to guide at least one precursor gas and at least one purge gas to different regions of the substrate S1 at the same time.

That is to say, in the cyclical epitaxial deposition system M1 in the embodiment of the present disclosure, different precursor gases and the at least one purge gas are separately introduced into the deposition chamber 11 simultaneously through the corresponding precursor gas nozzles 110a and 110c and the corresponding purge gas nozzle 110b.

In that instant embodiment, the precursor gas nozzles 110a and 110c include a first precursor gas nozzle 110a for guiding a first precursor gas and a second precursor gas nozzle 110c for guiding a second precursor gas. The first precursor gas and the second precursor gas may be of different kinds so as to form a monomolecular layer (monolayer) on the substrate S1. For example, if it is required to form a titanium nitride layer on the substrate S1, titanium tetrachloride (TiCl₄) is used as the first precursor gas; ammonia gas (NH₃) is used as the second precursor gas; and an inert gas, for example, argon gas (Ar), is used as the purge gas.

The embodiment of FIG. 1 shows an example in which there are three gas distribution modules 110 for description, and each gas distribution module 110 may include a plurality of nozzles (FIG. 1 shows an example in which there are six nozzles). The plurality of nozzles at least includes a first precursor gas nozzle 110a, at least one purge gas nozzle 110b, and at least one second precursor gas nozzle 110c which are sequentially arranged above the conveyance path in a moving direction of the substrate S1. In the instant embodiment, the first precursor gas nozzle 110a, the at least one purge gas nozzle 110b, and the at least one second precursor gas nozzle 110c are arranged roughly in a horizontal direction.

In this way, when the substrate S1 is continuously conveyed, a specific region of the substrate S1 passes below the first precursor gas nozzle 110a, the purge gas nozzle 110b, and the second precursor gas nozzle 110c successively, to complete one deposition cycle and form a single monomolecular layer on the specific region. Thus, after the specific region is driven to pass below multiple gas distribution modules 110 by driving the substrate S1, multiple monomolecular layers can be formed on the specific region. In the embodiment of FIG. 1 and FIG. 2, after the substrate S1 continuously passes below all the gas distribution modules 110, six deposition cycles can be implemented.

That is to say, the cyclical epitaxial deposition system M1 in the embodiment of the present disclosure basically still uses the principle of atomic layer deposition to form a film layer on the substrate S1. However, differences from a conventional atomic layer deposition apparatus lie in that, in the cyclical epitaxial deposition system M1 in the embodiment of the present disclosure, the conveyance device 13 is used to drive the substrate S1 to move. Furthermore, the gas distribution module 110 is also used to simultaneously introduce precursor gases required in each deposition cycle to different regions on the substrate S1.

It should be noted that, in each gas distribution module 110, the number of the precursor gas nozzles 110a, 110c and the number of the purge gas nozzles 110b are not limited to the foregoing example. However, a plurality of precursor gas nozzles (the first precursor gas nozzle 110a and the second precursor gas nozzle 110c) and a plurality of purge gas nozzles 110b may be alternately arranged.

In an embodiment, if formation of a monomolecular layer in each deposition cycle requires three kinds of precursor gases, the gas distribution module 110 may include three precursor gas nozzles. That is to say, the gas distribution module 110 may at least include a first precursor gas nozzle, a second precursor gas nozzle, and a third precursor gas nozzle which are sequentially arranged above the conveyance path in a moving direction of the substrate S1. Therefore, the embodiment of the present disclosure does not limit the number of the precursor gas nozzles.

The precursor gas may pass through the corresponding precursor gas nozzle 110a or 110c to form a precursor gas distribution region above the substrate S1, and two precursor gas distribution regions respectively formed through the two precursor gas nozzles 110a, 110c above the substrate Si do not overlap. Referring to FIG. 2, specifically, the first precursor gas and the second precursor gas may respectively pass through the corresponding first precursor gas nozzle 110a and second precursor gas nozzle 110c, to form a first precursor gas distribution region P1 and a second precursor gas distribution region P2 above different regions of the substrate S1. The first precursor gas distribution region P1 and the second precursor gas distribution region P2 do not overlap, thus preventing mutual diffusion of the first precursor gas and the second precursor gas before the first precursor gas is adsorbed onto the substrate S1

Likewise, the purge gas passes through the corresponding purge gas nozzle 110b to form a purge gas distribution region P3 above the substrate S1, and two precursor gas distribution regions (the first precursor gas distribution region P1 and the second precursor gas distribution region P2) are spaced apart from each other by at least one purge gas distribution region P3. In other words, the purge gas distribution region P3 is located between the first precursor gas distribution region P1 and the second precursor gas distribution region P2. The purge gas, which may be an inert gas, for example, argon gas, can remove excess first precursor gas above the substrate S1.

Moreover, each of the precursor gas nozzles (the first precursor gas nozzle 110a and the second precursor gas nozzle 110c) tapers at the bottom portion, so that the precursor gas flowing out of an opening end can rapidly flow to the surface of the substrate S1. In an embodiment, the shortest vertical distance d between the opening end of each precursor gas nozzle 110a or 110c and the surface of the substrate S1 ranges from 0.1 cm to 2.0 cm, thus preventing the precursor gases from mutually diffusing in a horizontal direction before being sprayed onto the substrate S1.

As shown in FIGS. 1 and 2, the cyclical epitaxial deposition system M1 in the embodiment of the present disclosure further includes a heating module 111 which is disposed in the deposition chamber 11 and located below the conveyance path, so as to heat the substrate S1 to a particular reaction temperature. In this embodiment, the heating module 111 includes a plurality of heaters 111a to 111c so as to respectively heat different sections of the substrate S1 to different temperatures at the same time. The heaters 111a to 111c are, for example, infrared radiation heaters, but the present disclosure is not limited thereto.

Referring to FIG. 1, the gas evacuation device 14 is in fluid communication with the main chamber 10 and used to evacuate the main chamber 10 to form a vacuum therein. The gas evacuation device 14 is, for example, a vacuum pump, which can remove gas from the main chamber 10 by suction, so that a pressure inside the main chamber 10 maintains a preset value. In addition, the gas evacuation device 14 is disposed below the main chamber 10, and can remove a precursor gas not adsorbed onto the substrate S1 and an excess purge gas by suction. Moreover, the vacuum apparatus 1 in this embodiment further includes a pressure and temperature sensor 15. The pressure and temperature sensor 15 is disposed in the main chamber 10 and can be used to measure a pressure and temperature inside the main chamber 10.

Referring to FIG. 1, the cyclical epitaxial deposition system M1 in the embodiment of the present disclosure further includes a cooling device 16 disposed on the conveyance path, and thus the substrate S1 conveyed out of the deposition chamber 11 can be guided to the cooling device 16. In this embodiment, the cooling device 16 is a roller equipped with a cooling pipeline.

After being conveyed from the deposition chamber 11 to the cooling device 16 and cooled, the substrate S1 is rolled up by the second feeding and receiving module 13b. However, the present disclosure is not limited thereto, and the cooling device 16 may also be omitted in other embodiments.

Referring to FIG. 1 and FIG. 2 in combination, the cyclical epitaxial deposition system M1 in the embodiment of the present disclosure further includes a gas pipeline system 2, at least one precursor storage unit 3 or 4, and at least one inert gas storage unit 5 or 6. The precursor storage unit 3 or 4 can supply a precursor gas to one of the precursor gas nozzles 110a and 110c through the gas pipeline system 2. Likewise, the inert gas storage unit 5 can supply a purge gas to the purge gas nozzle 110b also through the gas pipeline system 2.

The precursor storage unit 3 or 4 is used to store a precursor for reaction. In this embodiment, the cyclical epitaxial deposition system M1 includes a plurality of precursor storage units 3 and 4. In addition, the precursor storage units 3 and 4 include at least one of a gaseous precursor storage unit 3 and a liquid precursor storage unit 4.

Specifically, the gaseous precursor storage unit 3 may include a plurality of gas cylinders 30 and 31 used to store different precursor gases. The liquid precursor storage unit 4 may include a plurality of storage tanks 40, 41, and 42 used to store different liquid precursors. The liquid precursor may be heated and converters to gaseous precursors so as to output a precursor gas to the gas distribution module 110. The inert gas storage unit 5 may include at least one gas cylinder used to store an inert gas.

The gas pipeline system 2 includes a plurality of main gas pipelines 20, 21, and 22 and a plurality of gas distribution pipelines 200, 210, and 220. Each of the main gas pipelines 20, 21, and 22 is in fluid communication with the corresponding precursor gas nozzle 110a or 110c or purge gas nozzle 110b through the corresponding gas distribution pipeline 200, 210, or 220.

Specifically, the main gas pipelines 20, 21, and 22 may include precursor gas main pipelines 20 and 22, and an inert gas main pipeline 21. The gas distribution pipelines 200, 210, and 220 may be classified into precursor gas distribution pipelines 200 and 220 and an inert gas distribution pipeline 210. In this way, the precursor gas main pipelines 20 and 22 are in fluid communication with the corresponding precursor gas distribution pipelines 200 and 220 respectively, while the inert gas main pipeline 21 is in fluid communication with the corresponding inert gas distribution pipeline 210.

The gas cylinders 30 and 31 of the gaseous precursor storage unit 3 or the storage tanks 40, 41, and 42 of the liquid precursor storage unit 4 are in fluid communication with the corresponding precursor gas main pipelines 20 and 22 so as to supply the precursor gas. The precursor gas flows to the gas distribution module 110 through the corresponding one of the precursor gas distribution pipelines 200 and 220. In this embodiment, the precursor gas main pipelines 20 and 22 allow different precursor gases (the first precursor gas and the second precursor gas) to pass respectively.

The gas cylinder of the inert gas storage unit 5 is in fluid communication with the inert gas main pipeline 21, to introduce the inert gas into the inert gas main pipeline 21. Then the inert gas flows to the gas distribution module 110 through the inert gas distribution pipeline 210.

Referring to FIGS. 1 and 2, in this embodiment, the gas pipeline system 2 further includes a plurality of main flow control valves 20a, 21a and 22a, and a plurality of secondary flow control valves 200a, 210a, and 220a. Specifically speaking, the cyclical epitaxial deposition system M1 includes a control module (not shown in the figure), and the control module is electrically connected to the main flow control valves 20a, 21a and 22a, and the secondary flow control valves 200a, 210a, and 220a. As shown in FIG. 1, the main flow control valves 20a, 21a and 22a are respectively disposed on the main gas pipelines 20 to 22. Controlled by the control module, the main flow control valves 20a, 21a and 22a can control a flow of the precursor gas or inert gas passing through the main gas pipelines 20 to 22, respectively.

As shown in FIG. 2, the secondary flow control valves 200a, 210a, and 220a are respectively disposed on the gas distribution pipelines 200, 210, and 220. Controlled by the control module, the secondary flow control valves 200a, 210a, and 220a can independently control a flow of the precursor gas that enters each of the precursor gas nozzles 110a and 110c and a flow of the purge gas that enters the purge gas nozzle 110b.

In an embodiment, for a specific region on the substrate S1, by control with the secondary flow control valves 200a, 210a, and 220a, a sequence of spraying the precursor gas and the purge gas to the specific region in each deposition cycle may be changed.

For example, for one of the gas distribution modules 110, the first precursor gas is introduced to only one of the two first precursor gas nozzles 110a, but not introduced to the other first precursor gas nozzle 110a. Likewise, the second precursor gas is introduced to only one of the two second precursor gas nozzles 110c, but not introduced to the other second precursor gas nozzle 110c.

In this way, when the substrate Si continuously passes below one of the gas distribution modules 110, the specific region of the substrate Si may contact the first precursor gas, the purge gas, the second precursor gas, and the precursor gas successively, to form a deposition cycle in another form.

In addition, the gas pipeline system 2 further includes a plurality of preheating elements 20b to 22b respectively provided on the main gas pipelines 20 to 22. In other words, each of the preheating elements 20b to 22b is disposed on a corresponding one of the main gas pipelines 20 to 22. The preheating elements 20b to 22b are, for example, heater bands, which can heat the precursor gas in the main gas pipelines 20 to 22, so as to prevent condensation of the precursor gas before entering the gas distribution module 110.

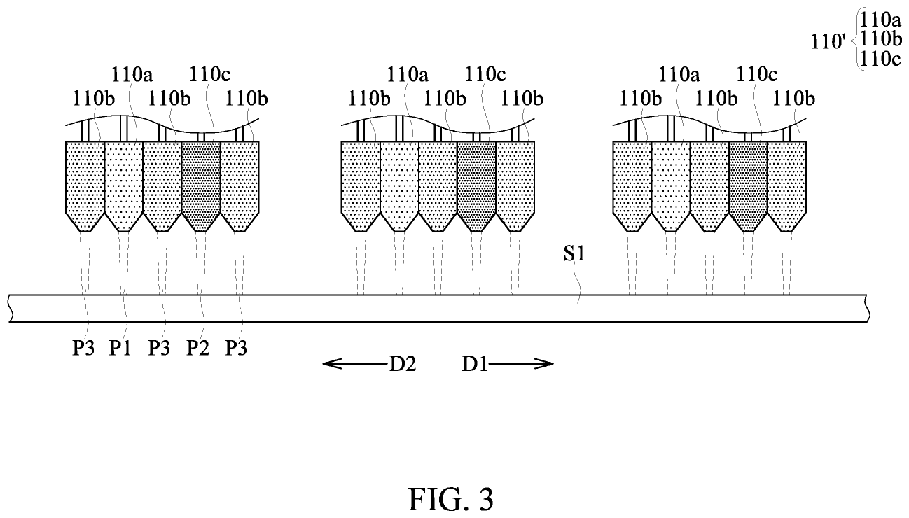

Referring to FIG. 3, FIG. 3 is a schematic diagram of a gas distribution module in another embodiment of the present disclosure. Identical or similar elements in the gas distribution module 110′ of this embodiment and the gas distribution module 110 of the foregoing embodiment have identical numerals, and identical parts are not described herein again. Specifically speaking, the gas distribution module 110 in FIG. 1 may be replaced with the gas distribution module 110′ shown in FIG. 3.

The gas distribution module 110′ in this embodiment includes a plurality of precursor gas nozzles 110a and 110c and a plurality of purge gas nozzles 110b. The plurality of precursor gas nozzles 110a and 110c includes a first precursor gas nozzle 110a for guiding a first precursor gas and a second precursor gas nozzle 110c for guiding a second precursor gas.

In this embodiment, the first precursor gas nozzle 110a, the second precursor gas nozzle 110c, and the purge gas nozzles 110b of the gas distribution module 110′ are arranged in a different manner from that in the foregoing embodiment. Specifically, the gas distribution module 110′ in this embodiment includes five gas nozzles 110a to 110c. That is to say, the gas distribution module 110′ includes at least one first precursor gas nozzle 110a, at least one second precursor gas nozzle 110c, and at least three purge gas nozzles 110b. In addition, the first precursor gas nozzle 110a is located between two purge gas nozzles 110b. Likewise, the second precursor gas nozzle 110c is located between two purge gas nozzles 110b.

As shown in FIG. 3, one purge gas nozzle 110b is disposed between every two adjacent first and second precursor gas nozzles 110a and 110c for supplying different precursor gases. In this way, a first precursor gas distribution region P1 and a second precursor gas distribution region P2 are spaced apart from each other by a purge gas distribution region P3, thus effectively preventing interdiffusion of two different precursor gases before they reach the surface of the substrate S1.

In this embodiment, the nozzles 110a to 110c of each gas distribution module 110′ are arranged in the following successive order: the purge gas nozzle 110b, the first precursor gas nozzle 110a, the purge gas nozzle 110b, the second precursor gas nozzle 110c, and the purge gas nozzle 110b. However, the present disclosure is not limited thereto.

Moreover, during a film deposition process, it is not necessary for the substrate S1 to move always towards the same direction; instead, the substrate S1 is likely to reciprocate. Referring to FIG. 3, in this embodiment, the substrate S1 may be driven by the conveyance device 13 to move towards a first direction D1 (from left to right) along the conveyance path, so that a surface of the substrate Si to be processed passes below the purge gas nozzle 110b, the first precursor gas nozzle 110a, the purge gas nozzle 110b, the second precursor gas nozzle 110c, and the purge gas nozzle 110b successively, to deposit an atomic layer. Afterwards, the conveyance device 13 may also drive the substrate S1 to move towards an opposite direction (namely, a second direction D2), to deposit another atomic layer.

### Advantageous Effects of the Embodiments

The present disclosure achieves the following advantageous effects. In the cyclical epitaxial deposition system M1 provided in the present disclosure, a conveyance device 13 is used to continuously convey a substrate S1 to/out of a deposition chamber 11 along a conveyance path, and a gas distribution module 110 includes a plurality of precursor gas nozzles 110a and 110c and a plurality of purge gas nozzles 110b that are not in communication with one another, so as to guide at least one precursor gas and at least one purge gas to different regions of the substrate S1 at the same time. By using the foregoing technical solutions, a film layer can be continuously formed on the substrate S1.

The cyclical epitaxial deposition system M1 provided in the present disclosure basically still uses the principle of atomic layer deposition to form a film layer. Compared with a conventional atomic layer deposition apparatus, the film thickness of the film layer fabricated by the cyclical epitaxial deposition system M1 of the present disclosure can also be precisely controlled. Furthermore, the film layer fabricated by the cyclical epitaxial deposition system M1 also has advantages such as desired uniformity and high step coverage. However, by using the cyclical epitaxial deposition system M1 of the present disclosure to form the film layer, the deposition time can be shorten, thereby being applicable to manufacturing elements or devices requiring mass production.

In addition, in a gas distribution module 110′ in an embodiment of the present disclosure, one of the purge gas nozzles 110b is disposed between every two adjacent first and second precursor gas nozzles 110a and 110c. In this way, the first precursor gas distribution region P1 and the second precursor gas distribution region P2 can be spaced apart from each other by the purge gas distribution region P3, thus effectively preventing interdiffusion of two different precursor gases before they reach the surface of the substrate S1.

The above disclosed content merely describes preferred and feasible embodiments of the present disclosure, and is not intended to limit the scope of patent application of the present disclosure. Therefore, any equivalent technical changes made according to the description and content of the drawings of the present disclosure all fall within the scope of the patent application of the present disclosure.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A cyclical epitaxial deposition system, comprising:
a deposition chamber;
a conveyance device used to continuously convey a substrate along a conveyance path through the deposition chamber; and
a gas distribution module disposed in the deposition chamber and located above the conveyance path, wherein the gas distribution module includes a plurality of precursor gas nozzles that are not in communication with one another and at least one purge gas nozzle, so as to guide at least one precursor gas and at least one purge gas to different regions of the substrate at the same time.

2. The cyclical epitaxial deposition system of claim 1, wherein the conveyance device includes a first feeding and receiving module and a second feeding and receiving module, the first feeding and receiving module is used to continuously convey the substrate to the deposition chamber, and the second feeding and receiving module is used to roll up the substrate conveyed out of the deposition chamber.

3. The cyclical epitaxial deposition system of claim 1, further comprising: a cooling device provided on the conveyance path, and used to cool the substrate conveyed out of the deposition chamber.

4. The cyclical epitaxial deposition system of claim 1, further comprising: a heating module disposed in the deposition chamber and located below the conveyance path, so as to heat the substrate.

5. The cyclical epitaxial deposition system of claim 1, further comprising: a pre-processing chamber and a plasma device located in the pre-processing chamber, wherein the pre-processing chamber and the deposition chamber are sequentially disposed on the conveyance path in a moving direction of the substrate and are separated from each other.

6. The cyclical epitaxial deposition system of claim 5, further comprising: a pre-processing heating module disposed in the pre-processing chamber and corresponding to the conveyance path, so as to heat the substrate.

7. The cyclical epitaxial deposition system of claim 1, wherein a shortest vertical distance between an opening end of each of the precursor gas nozzles and the surface of the substrate ranges from 0.1 cm to 2.0 cm.

8. The cyclical epitaxial deposition system of claim 1, wherein the precursor gas passes through the corresponding precursor gas nozzle to form a precursor gas distribution region above the substrate, and two precursor gas distribution regions respectively formed through the two precursor gas nozzles above the substrate do not overlap.

9. The cyclical epitaxial deposition system of claim 8, wherein the at least one purge gas passes through the corresponding purge gas nozzle to form a purge gas distribution region above the substrate, and the two precursor gas pipeline distribution regions are spaced apart from each other by the purge gas distribution region.

10. The cyclical epitaxial deposition system of claim 1, wherein the precursor gas nozzles include a first precursor gas nozzle for guiding a first precursor gas, and a second precursor gas nozzle for guiding a second precursor gas;
and the first precursor gas nozzle, the at least one purge gas nozzle, and the second precursor gas nozzle are sequentially disposed above the conveyance path in a moving direction of the substrate.

11. The cyclical epitaxial deposition system of claim 1, further comprising: a gas pipeline system which includes a plurality of main gas pipelines and a plurality of preheating elements, wherein each of the main gas pipelines is in fluid communication with the at least one purge gas nozzle or at least one of the precursor gas nozzles, and each of the preheating elements is disposed on the corresponding main gas pipeline.

12. The cyclical epitaxial deposition system of claim 11, further comprising: a precursor storage unit, wherein the main gas pipelines includes at least one precursor gas main pipeline, and the precursor storage unit supplies the precursor gas to one of the precursor gas nozzles through the at least one precursor gas main pipeline.

13. The cyclical epitaxial deposition system of claim 12, wherein the precursor storage unit includes at least one of a gaseous precursor storage unit and a liquid precursor storage unit.

14. The cyclical epitaxial deposition system of claim 11, wherein the gas pipeline system further comprises:
a plurality of gas distribution pipelines, wherein each of the main gas pipelines is in fluid communication with the corresponding precursor gas nozzle or purge gas nozzle through the corresponding gas distribution pipeline; and
a plurality of secondary flow control valves respectively disposed on the gas distribution pipelines, and used to control a flow of the precursor gas that enters each of the precursor gas nozzles and a flow of the purge gas that enters the at least one purge gas nozzle.

15. The cyclical epitaxial deposition system of claim 11, further comprising: an inert gas storage unit, wherein the main gas pipelines includes at least one inert gas main pipeline, and the inert gas storage unit supplies an inert gas to one of the at least one purge gas nozzles through the inert gas main pipeline.

16. The cyclical epitaxial deposition system of claim 15, wherein the gas pipeline system further comprises:
at least one inert gas distribution pipeline, wherein the inert gas main pipeline is in fluid communication with the at least one purge gas nozzle through the at least one inert gas distribution pipeline.

17. The cyclical epitaxial deposition system of claim 1, wherein two of the precursor gas nozzles are used to guide two different precursor gases, respectively, the gas distribution module includes three purge gas nozzles, and each one of the precursor gas nozzles is located between two of the purge gas nozzles.
